(19) United States
(12) Patent Application Publication
(10) Pub. No.: US 2020/0098595 A1
(43) Pub. Date: Mar. 26, 2020

(54) SEMICONDUCTOR MANUFACTURING APPARATUS AND METHOD FOR OPERATING THE SAME

(71) Applicant: NANYA TECHNOLOGY CORPORATION, New Taipei City (TW)

(72) Inventor: Chung-Lin HUANG, Taoyuan City (TW)

(21) Appl. No.: 16/137,224

(22) Filed: Sep. 20, 2018

(51) Int. Cl. H01L 21/67; H01J 37/32

(52) U.S. Cl. CPC H01L 21/67069; H01J 37/32082; H01J 37/3244; H01J 2237/0047; H01J 37/32532; H01J 2237/334; H01J 2237/332; H01J 37/32834

(57) ABSTRACT

The present disclosure provides a semiconductor manufacturing apparatus for processing a semiconductor subject. The semiconductor manufacturing apparatus includes a processing chamber, a first electrode, a second electrode, an RF power supply, and one or more light generators. The first electrode is disposed within the processing chamber. The second electrode is disposed within the processing chamber and substantially beneath the first electrode. The RF power supply is electrically connected to the first electrode. The one or more light generators are disposed within the processing chamber for irradiating the semiconductor subject, thereby releasing charges from the semiconductor subject.

### TECHNICAL FIELD

The present disclosure relates to an apparatus and a method for operating the apparatus, and more particularly, to a semiconductor manufacturing apparatus and a method for operating the manufacturing apparatus.

### DISCUSSION OF THE BACKGROUND

Electronics with semiconductor devices are essential for many modern applications. With the advancement of electronic technology, the semiconductor devices are becoming smaller in size while providing greater functionality and having greater amounts of integrated circuitry. Fabrication of semiconductor devices typically involves placing numerous components over a semiconductor substrate.

During dry etching processes including plasma formation, charges on processing wafers tend to be easily induced. In particular, for a high bias voltage etching process, in order to achieve a high aspect ratio structure with an anisotropic etch, surfaces of conductor layers easily accumulate electron charge. The built-up voltage potential on the conductor layers can easily incur arcing phenomenon if the conductor is not effectively grounded or if the charge on the conductor layers is not properly released.

Currently, chamber de-chuck is used to release charge after an etch process. However, when the target etching geometry is too small to connect to a substrate, the de-chuck step may not effectively release the charge on the small-geometry conductor.

This Discussion of the Background section is provided for background information only. The statements in this Discussion of the Background are not an admission that the subject matter disclosed in this section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides a semiconductor manufacturing apparatus for processing a semiconductor subject. The semiconductor manufacturing apparatus comprises a processing chamber; a first electrode disposed within the processing chamber; a second electrode disposed within the processing chamber and substantially beneath the first electrode; an RF power supply electrically connected to the first electrode; and a plurality of light generators disposed within the processing chamber for irradiating the semiconductor subject, thereby releasing charge on the semiconductor subject.

In some embodiments, a wavelength of the light generators is in a range of 280 nm to 400 nm.

In some embodiments, the light generators are spaced apart from each other at equal intervals in a horizontal direction.

In some embodiments, the light generators are disposed above the semiconductor subject.

In some embodiments, the semiconductor manufacturing apparatus further comprises a gas supply system connected to a gas inlet of the processing chamber and configured to introduce one or more chemical gases into the processing chamber.

In some embodiments, the semiconductor manufacturing apparatus further comprises an exhaust system connected to a gas outlet of the processing chamber and configured to remove the chemical gases from the processing chamber.

In some embodiments, the second electrode is grounded.

In some embodiments, the second electrode is floated.

In some embodiments, the second electrode is arranged parallel to the first electrode.

In some embodiments, the semiconductor manufacturing apparatus is implemented to perform a plasma-based process.

In some embodiments, the semiconductor manufacturing apparatus is implemented to perform an etching or deposition process.

Another aspect of the present disclosure provides a method for operating a semiconductor manufacturing apparatus. The semiconductor manufacturing apparatus comprises a chamber, a first electrode and a second electrode parallel to the first electrode arranged within the chamber, an RF power supply to electrically connect to the first electrode, one or more light generators arranged within the processing chamber, and a gas supply system and an exhaust system both in communication with the processing chamber. The method comprises moving a semiconductor subject into the processing chamber; turning on the RF power supply for providing a bias power to excite free electrons; turning on the light generators for generating ultraviolet light to excite the free electrons on the semiconductor subject; turning off the RF power supply; and transferring the semiconductor subject out of the processing chamber.

In some embodiments, the method further comprises a step of turning off the light generators after turning off the RF power supply.

In some embodiments, the method further comprises a step of turning off the light generators after the semiconductor subject is transferred out of the processing chamber.

In some embodiments, the method further comprises a step of turning on the light generators when the RF power supply is turned on.

In some embodiments, the RF power supply and the light generators are simultaneously turned on.

In some embodiments, the method further comprises a step of introducing one or more chemical gases into the processing chamber when the RF power supply is turned on.

In some embodiments, the method further comprises a step of stopping the introduction of the chemical gases into the processing chamber when the RF power supply is turned off.

In some embodiments, the method further comprises a step of purging the chemical gases from the processing chamber when the RF power supply is turned off.

In some embodiments, a wavelength of the ultraviolet light is in a range of 10 nm to 400 nm.

In some embodiments, the wavelength of the ultraviolet light is in a range of 280 nm to 400 nm.

In some embodiments, the semiconductor substrate is mounted on the second electrode.

In some embodiments, the method is implemented in the etching process or the deposition process.

With the above-mentioned configurations, the free electrons accumulated on the semiconductor subject during etching or deposition process can be released.

The foregoing has outlined rather broadly the features and technical advantages of the present disclosure in order that the detailed description of the disclosure that follows may be better understood. Additional features and technical advantages of the disclosure are described hereinafter, and form the subject of the claims of the disclosure. It should be appreciated by those skilled in the art that the concepts and specific embodiments disclosed may be utilized as a basis for modifying or designing other structures, or processes, for carrying out the purposes of the present disclosure. It should also be realized by those skilled in the art that such equivalent constructions do not depart from the spirit or scope of the disclosure as set forth in the appended claims.

### BRIEF DESCRIPTION OF THE DRAWINGS

A more complete understanding of the present disclosure may be derived by referring to the detailed description and claims. The disclosure should also be understood to be coupled to the figures' reference numbers, which refer to similar elements throughout the description.

FIG. 1 is a cross-sectional view of a semiconductor manufacturing apparatus in accordance with some embodiments of the present disclosure.

FIG. 2 is a flow diagram of a method for operating the manufacturing apparatus in FIG. 1 in accordance with some embodiments of the present disclosure.

FIGS. 3A to 3F are schematic views of operating the manufacturing apparatus in FIG. 1 by the method of FIG. 2 in accordance with some embodiments of the present disclosure.

FIG. 4 is a flow diagram of a method for operating the semiconductor manufacturing apparatus in accordance with some embodiments of the present disclosure.

FIG. 5 is schematic view of operating light generators in accordance with some embodiments of the present disclosure.

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that, although the terms first, second, third, etc. may be used herein to describe various elements, components, regions, layers or sections, these elements, components, regions, layers or sections are not limited by these terms. Rather, these terms are merely used to distinguish one element, component, region, layer or section from another region, layer or section. Thus, a first element, component, region, layer or section discussed below could be termed a second element, component, region, layer or section without departing from the teachings of the present inventive concept.

The terminology used herein is for the purpose of describing particular example embodiments only and is not intended to be limited to the present inventive concept. As used herein, the singular forms “a,” “an” and “the” are intended to include the plural forms as well, unless the context clearly indicates otherwise. It shall be further understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

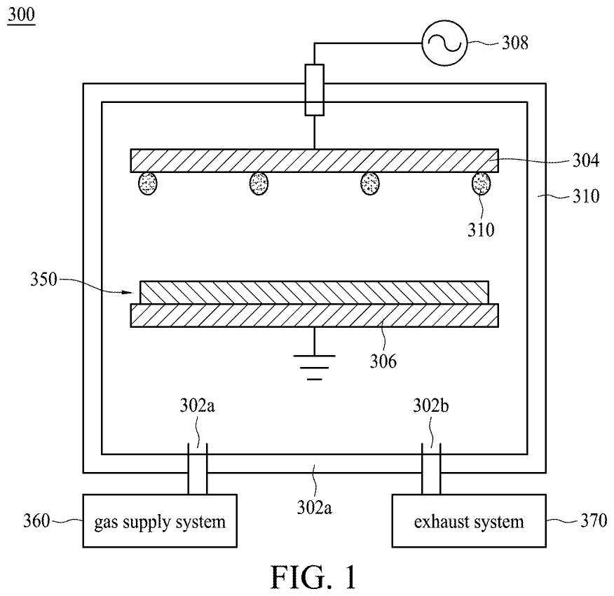

FIG. 1 is a sectional view of a semiconductor manufacturing apparatus 300 in accordance with some embodiments of the present disclosure. Referring to FIG. 1, in some embodiments, the semiconductor manufacturing apparatus 300 is configured to process a semiconductor subject 350, such as a semiconductor wafer, and the semiconductor manufacturing apparatus 300 is configured for exciting accumulated free electrons on a (wafer) surface of the semiconductor subject 350. The semiconductor manufacturing apparatus 300 includes a processing chamber 302; a first electrode 304 disposed within the processing chamber 302; a second electrode 306 disposed within the processing chamber 302 and substantially beneath the first electrode 304; an RF power supply 308 electrically connected to the first electrode 304; one or more light generators 310 disposed within the processing chamber 302 for irradiating the semiconductor subject 350, thereby releasing the charge from the semiconductor subject 350.

In some embodiments, the processing chamber 302 is particularly useful for performing a plasma-based process. In some embodiments, the processing chamber 302 is useful for performing an etching or disposing process. In some embodiments, the processing chamber 302 is a vacuum chamber. In some embodiments, the processing chamber 302 has a gas inlet 302a so as to communicate with a gas supply system 360. In some embodiments, the processing chamber 302 has a gas outlet 302b so as to communicate with an exhaust system 370. In some embodiments, the gas inlet 302a and the gas outlet 302b are disposed at a bottom wall of the chamber 302.

In some embodiments, the second electrode 306 is parallel to the first electrode 304. In some embodiments, the first electrode 304 and the second electrode 306 form a pair of parallel electrodes. In some embodiments, the second electrode 306 is insulated from the first electrode 304. In some embodiments, the second electrode 306 is connected to ground, thereby forming a capacitance between the first electrode 304 and the second electrode 306. In some embodiments, the second electrode 306 is electrically floated. In some embodiments, the semiconductor subject 350 is mounted on the second electrode 306.

In some embodiments, the RF power supply 308 is configured to supply a high-frequency power. In some embodiments, the high-frequency power supplied by the RF power supply 308 is provided to function as a voltage source for controlling the potential of the first electrode 306 so that the semiconductor subject 350 is given a negative potential with respect to the plasma.

In some embodiments, the light generators 310 are disposed above the semiconductor subject 350. In some embodiments, the light generators 310 are disposed near the first electrode 104. In some embodiments, the light generators 310 are spaced apart from each other at equal intervals in a horizontal direction. In some embodiments, the light generators 310 are light tubes, light bulbs, or light emitting diodes (LEDs). The light generators 310 are mounted on the first electrode 304 and are electrically insulated from the first electrode 304.

In some embodiments, the light generators 310 are configured for generating light with energy sufficient to excite one or more free electrons accumulated on the semiconductor subject 350 during an etch or deposition process. In some embodiments, the light generators 310 are configured for irradiating ultraviolet light. In some embodiments, a wavelength of the ultraviolet light from the light generators 310 is in a range of 10 nm to 400 nm. In some embodiments, the wavelength of the ultraviolet light is in a range of 280 nm to 400 nm.

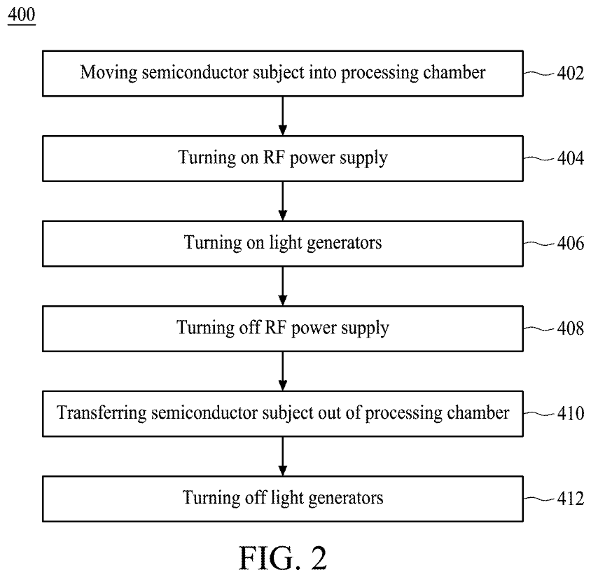

In the present disclosure, a method for operating a semiconductor manufacturing apparatus 300 is also disclosed. In some embodiments, accumulation of the charge in a semiconductor subject 350 is released by the method. The method includes a number of operations and the description and illustration are not deemed as a limitation as the sequence of the operations. FIG. 2 is a flowchart of a method 400 for operating the semiconductor manufacturing apparatus 300 shown in FIG. 1. The method 400 includes a number of operations (402, 404, 406, 408, and 410).

The semiconductor manufacturing apparatus 300 includes a chamber 302, a first electrode 304 and the second electrode 306 parallel to the first electrode 304 arranged within the chamber 302, an RF power supply 308 to electrically connect to the first electrode 304, one or more light generators 310 arranged within the processing chamber 302, and a gas supply system 360 and an exhaust system 370 both in communication with the processing chamber 302.

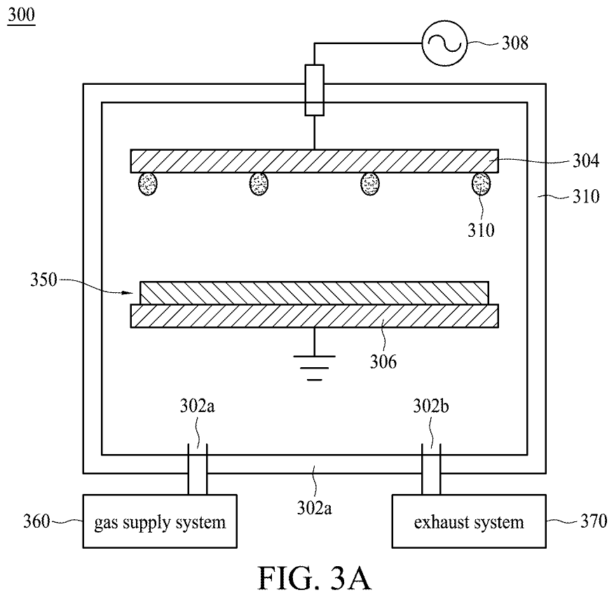

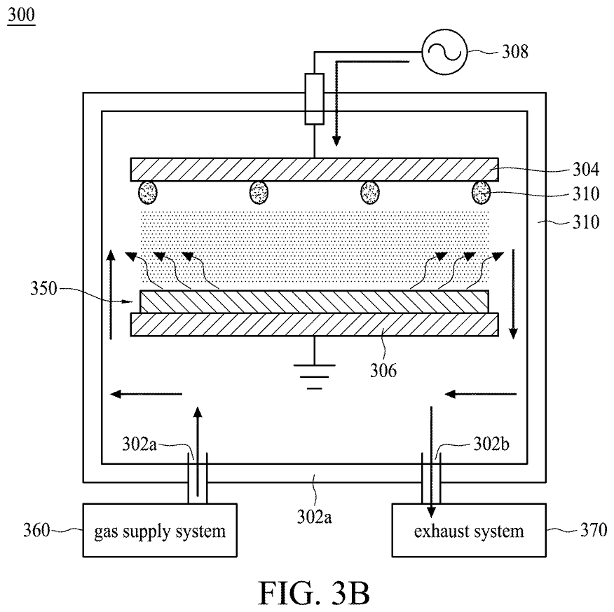

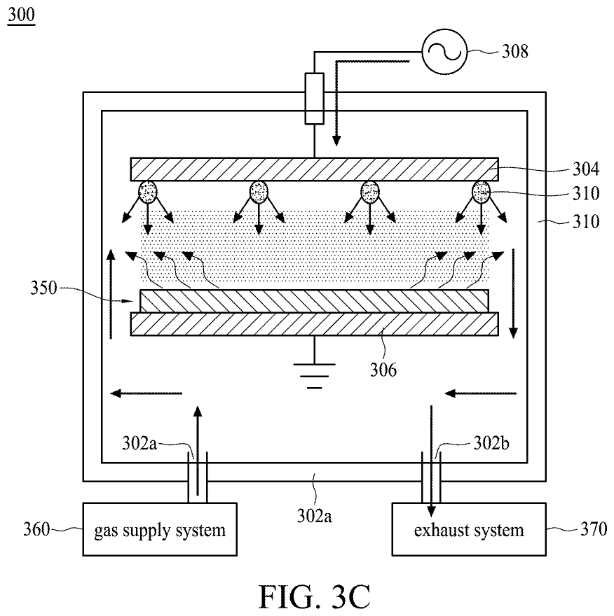

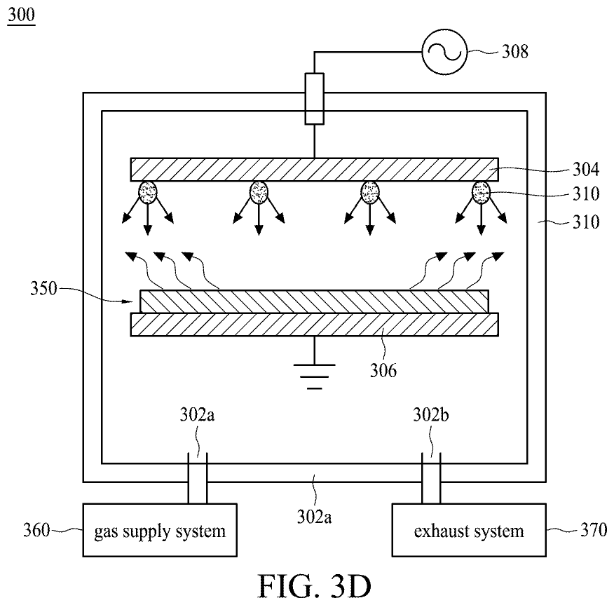

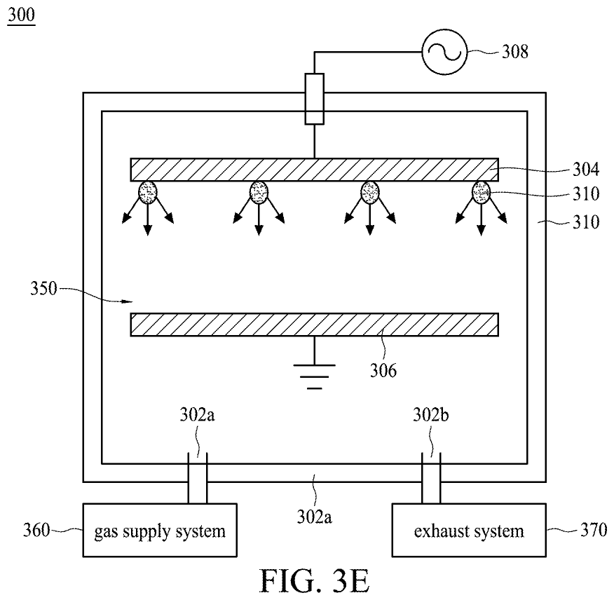

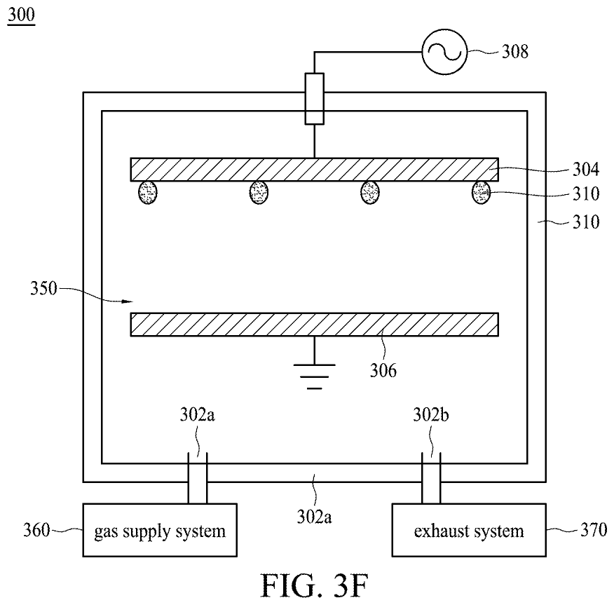

In operation 402, a semiconductor subject 350 is moved into the processing chamber 302, as shown in FIG. 3A. In some embodiments, the semiconductor subject 350 is a semiconductor wafer. In some embodiments, the semiconductor subject 350 is mounted on the second electrode 306 and is grounded.

In operation 404, the RF power supply 308 is turned on for providing a bias power to excite free electrons for an etching process or a deposition process, as shown in FIG. 3B. During the etching process or deposition process, charges are gradually accumulated on semiconductor subject 350 with ionized molecules forming chemically reactive and ionic species. The high bias voltage provided by the RF power supply 308 in the processing chamber 302 is configured to force ionized molecules to the surface of the semiconductor subject 350 and react with semiconductor subject 350. In some embodiments, the gas supply system 360 introduces one or more chemical gases into the processing chamber 302 when the RF power supply 308 is turned on. In some embodiments, the chemical gases include argon (Ar), tetrafluoromethane (CF₄), and oxygen (O₂).

In operation 406, the light generators 310 are turned on for irradiating ultraviolet light to excite the free electrons on the semiconductor subject 350, as shown in FIG. 3C. In some embodiments, a wavelength of the ultraviolet light from the light generators 310 is in a range of 10 nm to 400 nm. In some embodiments, the wavelength of the ultraviolet light is in a range of 280 nm to 400 nm. In some embodiments, the RF power supply 308 and the light generators 310 are simultaneously turned on. In some embodiments, the light generators 310 are turned on after the RF power supply 308 is turned on. In some embodiments, the chemical gases within the processing chamber are purged by the exhaust system 370 when the RF power supply 308 is turned off.

In operation 408, the RF power supply 308 is turned off, as shown in FIG. 3D. In some embodiments, the light generators 310 are turned on when the RF generator 308 is turned off In some embodiments, the light generators 310 are turned on when the RF generator 308 is turned on for a predetermined length of time.

In operation 410, the semiconductor subject 350 is transferred out of the processing chamber 302, as shown in FIG. 3E. In some embodiments, the semiconductor subject 350 is transferred out of the processing chamber 302 after the free electrons are released.

In operation 412, the light generators 310 are turned off after the semiconductor subject 350 is transferred out of the processing chamber 302, as shown in FIG. 3F.

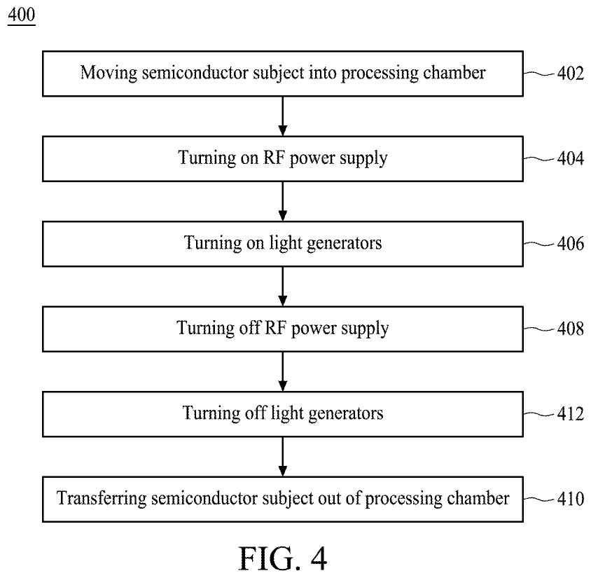

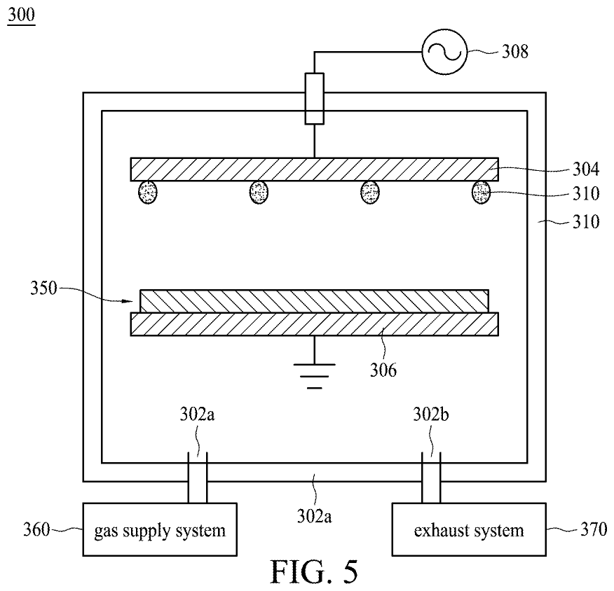

In some embodiments, after the RF generator 308 is turned off, the light generators 310 are turned off before the semiconductor subject 350 is transferred out of the processing chamber 302, as shown in FIG. 4 and FIG. 5.

In conclusion, with the above-mentioned configurations, the free electrons accumulated on the semiconductor subject 350 during an etching or deposition process can be released to prevent the semiconductor subject 350 from being damaged.

One aspect of the present disclosure provides a semiconductor manufacturing apparatus configured to process a semiconductor subject. The semiconductor manufacturing apparatus comprises a processing chamber, a first electrode, a second electrode, an RF power supply, and one or more light generators. The first electrode is disposed within the processing chamber. The second electrode is disposed within the processing chamber and substantially beneath the first electrode. The RF power supply is electrically connected to the first electrode. The one or more light generators are disposed within the processing chamber for illuminating the semiconductor subject, thereby releasing a charge from the semiconductor subject.

Another aspect of the present disclosure provides a method for operating a semiconductor manufacturing apparatus. The semiconductor manufacturing apparatus comprises a chamber, a first electrode and the second electrode parallel to the first electrode arranged within the chamber, an RF power supply to electrically connect to the first electrode, one or more light generators arranged within the processing chamber, and a gas supply system and an exhaust system both in communication with the processing chamber. The method comprises moving a semiconductor subject into the processing chamber; turning on the RF power supply for providing a bias power to excite free electrons; turning on the light generators for irradiating ultraviolet light to excite the free electrons on the semiconductor subject; turning off the RF power supply; and transferring the semiconductor subject out of the processing chamber.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, and composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

1. A semiconductor manufacturing apparatus for processing a semiconductor subject having one or more conductive layer, the semiconductor manufacturing apparatus comprising:
a processing chamber;
a first electrode disposed within the processing chamber;
a second electrode disposed within the processing chamber and substantially beneath the first electrode;
an RF power supply electrically connected to the first electrode; and
one or more light generators disposed within the processing chamber for irradiating the semiconductor subject, thereby releasing charge on the semiconductor subject, wherein the light generators are mounted on the first electrode electrically connecting to the RF power supply and are electrically insulated from the first electrode.

2. The semiconductor manufacturing apparatus of claim 1, wherein the light generators are configured to irradiate a light with a wavelength in a range of 10 nm to 400 nm.

3. The semiconductor manufacturing apparatus of claim 1, wherein the light generators are spaced apart from each other at equal intervals in a horizontal direction.

4. The semiconductor manufacturing apparatus of claim 1, wherein the light generators are disposed above the semiconductor subject.

5. The semiconductor manufacturing apparatus of claim 1, further comprising a gas supply system connected to a gas inlet of the processing chamber and configured to introduce one or more chemical gases into the processing chamber.

6. The semiconductor manufacturing apparatus of claim 1, further comprising an exhaust system connected to a gas outlet of the processing chamber and configured to remove the chemical gases from the processing chamber.

7. The semiconductor manufacturing apparatus of claim 1, wherein the second electrode is parallel to the first electrode.

8. The semiconductor manufacturing apparatus of claim 1, wherein the second electrode is grounded.

9. The semiconductor manufacturing apparatus of claim 1, wherein the second electrode is floated.

10. A method for operating a semiconductor manufacturing apparatus, the semiconductor manufacturing apparatus comprising a chamber, a first electrode and the second electrode parallel to the first electrode arranged within the chamber, an RF power supply to electrically connect to the first electrode, one or more light generators arranged within the processing chamber, and a gas supply system and an exhaust system both in communication with the processing chamber, the method comprising:
moving a semiconductor subject into the processing chamber;
turning on the RF power supply for providing a bias power to force ionized molecules to a surface of the semiconductor subject and react with the semiconductor subject;
turning on the light generators for irradiating ultraviolet light to excite the free electron on the semiconductor subject;
turning off the RF power supply; and
transferring the semiconductor subject out of the processing chamber.

11. The method of claim 10, further comprising:
turning off the light generators after turning off the RF power supply.

12. The method of claim 10, further comprising:
turning off the light generators after the semiconductor subject is transferred out of the processing chamber.

13. The method of claim 10, further comprising:
turning on the light generators when the RF power supply is turned on.

14. The method of claim 10, wherein the RF power supply and the light generators are simultaneously turned on.

15. The method of claim 10, further comprising:
introducing one or more chemical gases into the processing chamber when the RF power supply is turned on.

16. The method of claim 15, further comprising:
stopping the introduction of the chemical gases into the processing chamber when the RF power supply is turned off.

17. The method of claim 16, further comprising:
purging the chemical gases from the processing chamber when the RF power supply is turned off.

18. The method of claim 10, wherein a wavelength of the ultraviolet light is in a range of 10 nm to 400 nm.

19. The method of claim 10, wherein a wavelength of the ultraviolet light is in a range of 280 nm to 400 nm.

20. The method of claim 10, wherein the semiconductor substrate is mounted on the second electrode.
